(19) United States
(12) Patent Application Publication
(10) Pub. No.: US 2016/0369389 A1
(43) Pub. Date: Dec. 22, 2016

(54) MASK ASSEMBLY FOR THIN FILM DEPOSITION AND ORGANIC LIGHT-EMITTING DISPLAY APPARATUS FABRICATED USING THE SAME

(71) Applicant: Samsung Display Co., Ltd., Yongin-si (KR)

(72) Inventors: Junhyeuk KO, Yongin-si (KR); Sangshin LEE, Yongin-si (KR); Mingoo KANG, Yongin-si (KR)

(21) Appl. No.: 14/982,908

(22) Filed: Dec. 29, 2015

(30) Foreign Application Priority Data
Jun. 22, 2015 (KR) 10-2015-0088710

(51) Int. Cl. C23C 14/04; H01L 51/52; H01L 27/32

(52) U.S. Cl. CPC C23C 14/042; H01L 27/3248; H01L 51/5237

(57) ABSTRACT

A mask assembly for thin film deposition including a mask frame defining and surrounding an opening, and a mask coupled to the mask frame and having a plurality of deposition pattern units formed in a longitudinal direction of the mask and spaced apart from each other. The respective deposition pattern units include a deposition area, and each deposition area is divided into a plurality of pattern portions.

### CROSS-REFERENCE TO RELATED APPLICATION

This application claims priority from and the benefit of Korean Patent Application No. 10-2015-0088710, filed on Jun. 22, 2015, which is hereby incorporated by reference for all purposes as if fully set forth herein.

### BACKGROUND

Field

Exemplary embodiments relate to a mask assembly for thin film deposition. More particularly, exemplary embodiments relate to an organic light-emitting display apparatus fabricated using the same.

Discussion of the Background

Generally, an organic light-emitting display apparatus having a thin film transistor may be used in a mobile apparatus, such as a smart phone, a tablet personal computer, a laptop computer, a digital camera, or a portable information terminal. The organic light-emitting display apparatus having a thin film transistor may also be used in non-mobile apparatuses, such as a desktop computer, a television set, or a billboard.

A thin film of the organic light-emitting display apparatus is formed using a deposition process. The thin film of the organic light-emitting display apparatus is formed by placing a mask having the same pattern as the thin film on a substrate and depositing a raw material of the thin film on the substrate.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a mask assembly for thin film deposition, and an organic light-emitting display apparatus fabricated using the same.

Additional aspects will be set forth in the detailed description which follows, and, in part, will be apparent from the disclosure, or may be learned by practice of the inventive concept.

An exemplary embodiment discloses a mask assembly for thin film deposition may include a mask frame defining and surrounding an opening; and a mask coupled to the mask frame and having a plurality of deposition pattern units formed in a longitudinal direction of the mask and spaced apart from each other. The respective deposition pattern units include a deposition area, and each deposition area is divided into a plurality of pattern portions.

An exemplary embodiment also discloses an organic light-emitting display apparatus fabricated using a mask assembly for thin film deposition, in which the organic light-emitting display may include a display substrate, a thin film transistor disposed on the display substrate, an organic light-emitting device including a first electrode electrically connected to the thin film transistor and disposed on each sub-pixel of the display substrate, an intermediate layer including a light emissive layer disposed on the first electrode, and a second electrode disposed on the intermediate layer, and an encapsulation substrate to cover the organic light-emitting device. A pattern of the sub-pixel may include at least one first deposition pattern extended in one direction of the display substrate and a plurality of second deposition patterns disposed in both sides of the first deposition pattern with respect to the first deposition pattern, and the first deposition pattern and the second deposition patterns may be repeatedly arranged in the other direction of the display substrate.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a perspective view illustrating a mask assembly for thin film deposition according to an exemplary embodiment of the present inventive concept.

FIG. 2 is a perspective view illustrating a partial-cut portion of the divisional mask of FIG. 1.

FIG. 3 is an enlarged plan view illustrating a pattern of FIG. 2.

FIG. 4A is a picture showing a measured deformation amount of a mask according to a comparative example.

FIG. 4B is a picture showing a measured deformation amount of a mask according to the present embodiment.

FIG. 5 is a diagram illustrating deposition of a thin film on a substrate using the mask assembly of FIG. 1.

FIG. 6 is a cross-sectional view illustrating an organic light-emitting display apparatus according to an embodiment of the present inventive concept.

FIG. 7 is an enlarged plan view illustrating a red-light emitting layer using the divisional mask of FIG. 1.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. The regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

Hereinafter, a mask assembly for a thin film deposition and an organic light-emitting display apparatus formed using the same according to exemplary embodiments of the present inventive concept will be explained with referent to the drawings.

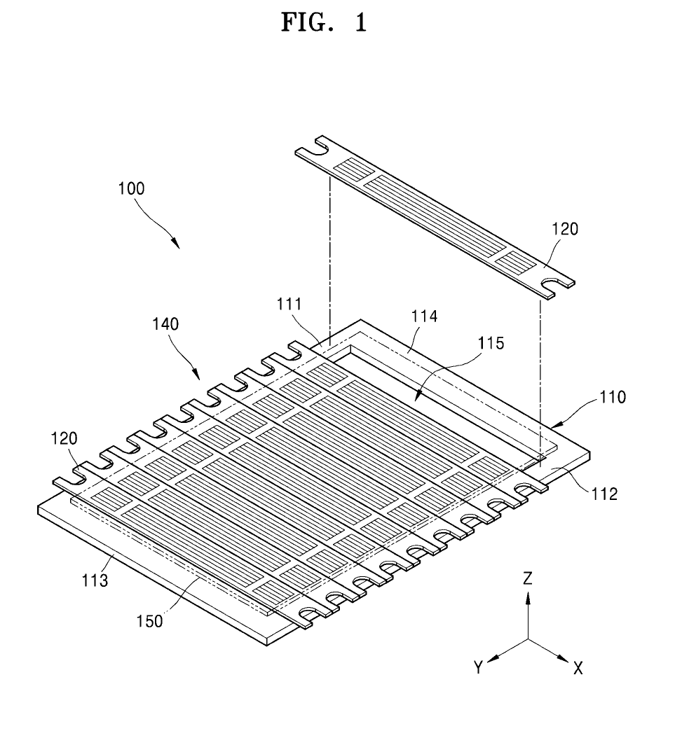

FIG. 1 is a perspective view illustrating a mask assembly 100 for thin film deposition, according to an exemplary embodiment of the present inventive concept.

Referring to FIG. 1, the mask assembly 100 may include a mask frame 110 and a mask 140 having a plurality of divisional masks 120.

The mask frame 110 may include an opening 115 and a plurality of frames, for example, first to fourth frames 111 to 114, surrounding the opening 115. The plurality of frames, namely, first to fourth frames 111 to 114 in the exemplary embodiment shown in FIG. 1, are connected to each other.

The mask frame 110 may include the first frame 111 and the second frame 112 disposed to face each other in a direction X and extended in a direction Y, and the third frame 113 and the fourth frame 114 disposed to face each other in the direction Y and extended in the direction X. The first frame 111, the second frame 112, the third frame 113, and the fourth frame 114 are connected to each other to form a rectangular frame. The mask frame 110 may include a material having only a small deformation during welding the mask 140, for example, a metal with high rigidity.

The mask 140 may be disposed on the mask frame 110. In order to form a precise deposition pattern, the degree of attachment may be increased between the mask 140 and a display substrate 150 disposed on the mask 140, which may also reduce a shadow. In one exemplary embodiment, the mask 140 may be formed using a thin plate. A material of the mask 140 may be stainless steel, invar, nickel (Ni), cobalt (Co), a nickel alloy, or a nickel-cobalt alloy.

The mask 140 may include the plurality of divisional masks 120 separated from each other in the direction Y to prevent sagging caused by their weight. The divisional masks 120 may be a stick. In one exemplary embodiment, the divisional masks 120 are not limited to one structure as long as a width of the mask 140 is less than a length of the mask 140. A tensile direction of the mask 140 may be a longitudinal direction.

The divisional masks 120 may be separated from each other in the direction Y crossing the tensile direction (X direction). In detail, the divisional masks 120 are continuously arranged between the third frame 113 and the fourth frame 114, and both ends of each divisional mask 120 are welded and fixed to the first frame 111 and the second frame 112. The plurality of divisional masks 120 may cover the opening 115.

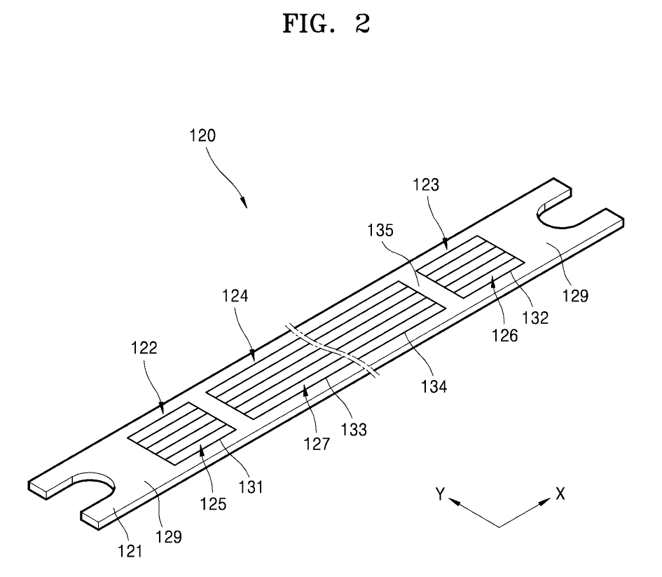

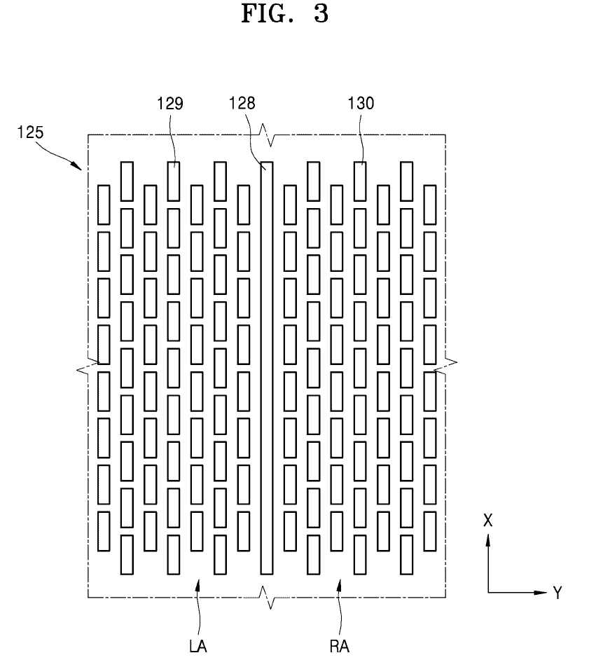

FIG. 2 is a perspective view illustrating a partial-cut portion of the divisional mask 120 of FIG. 1, and FIG. 3 is an enlarged plan view illustrating a pattern portion 125 of FIG. 2.

Referring to FIGS. 2 and 3, the divisional mask 120 may include a main body 121 consisting of a thin metal plate. The divisional mask 120 may include a plurality of deposition pattern units, for example, first, second, and third deposition pattern units 122, 123, and 124. The deposition pattern units, namely, the first, second, and third deposition pattern units 122, 123, and 124, may be arranged to be spaced apart from each other in a longitudinal direction (direction X) of the divisional mask 120. A rib 35 may be formed between the adjacent deposition pattern units 122, 123, and 124. The rib 135 may connect the deposition pattern units 122, 123, and 124 disposed adjacent to each other.

The first deposition pattern unit 122 and the second deposition pattern unit 123 may be disposed at both end portions of the divisional mask 120 in the longitudinal direction, and the third deposition pattern unit 124 may be disposed between the both end portions of the divisional mask 120 in the longitudinal direction.

The first deposition pattern unit 122 may be disposed at one end of the divisional mask 120 in the longitudinal direction, and the second deposition pattern unit 123 may be disposed at the other end of the divisional mask 120 in the longitudinal direction. The first deposition pattern unit 122 and the second deposition pattern unit 123 may form single deposition areas, for example, first and second single deposition areas 131 and 132, respectively.

In detail, the first deposition pattern unit 122 may include the first single deposition area 131. The second deposition pattern unit 123 may include the second single deposition area 132. The first single deposition area 131 and the second single deposition area 132 may respectively correspond to a unit display apparatus, for example, a single cell area of a unit organic light-emitting display apparatus.

The third deposition pattern unit 124 disposed between the both end portions of the divisional mask 120 may include a plurality of deposition areas 133 and 134 that are different from the first deposition pattern unit 122 and the second deposition pattern unit 123. The plurality of deposition areas 133 and 134 may be a plurality of cell areas corresponding to a plurality of unit display apparatuses, respectively.

In detail, the plurality of deposition areas 133 and 134 may include an area in which the first deposition area 131 and the second deposition area 132 respectively provided in the first deposition pattern unit 122 and the second deposition pattern unit 123 are continuously arranged. The respective deposition areas 133 and 134 correspond to each unit display apparatus, and the deposition areas 133 and 134 may not be spaced apart from each other but continuously arranged in the area.

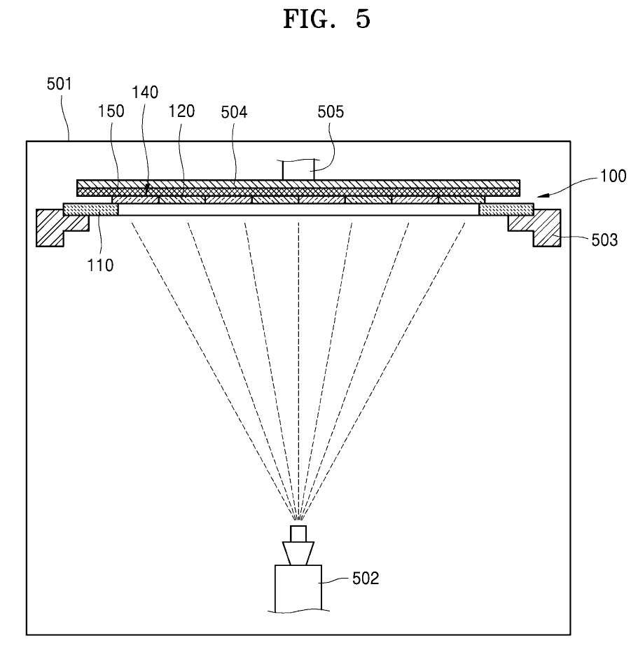

Since only the plurality of deposition areas 133 and 134 corresponding to deposition patterns of the display apparatus are in an area in which the third deposition pattern unit 124 disposed between the both end portions of the divisional mask 120 is formed, the area may be an area where repulsion may not be generated by a magnet (504 of FIG. 5) to support the divisional mask 120 using magnetic force during a deposition process.

On the other hand, since an area where the first deposition pattern unit 122 and the second deposition pattern unit 123 are formed is connected to a non-deposition pattern area 129 formed at the end of the divisional mask 120 on the outside of the first deposition pattern unit 122 and the second deposition pattern unit 123, the divisional mask 120 may be deformed while the magnet 504 supports the divisional mask 120. Accordingly, the first and second single deposition areas 131 and 132 may be respectively formed at the end portions of the divisional mask 120 in the longitudinal direction of the divisional mask 120 in order to reduce the deformation of the divisional mask 120.

In the present exemplary embodiment, the third deposition pattern unit 124 includes the two deposition areas 133 and 134 corresponding to the two unit display apparatuses. However, the third deposition pattern unit 124 may include a structure in which more than two deposition areas are continuously arranged.

In one exemplary embodiment, a size of the third deposition pattern unit 124 disposed between the both end portions of the divisional mask 120 in the longitudinal direction may be larger than a size of the first deposition pattern unit 122 and the second deposition pattern unit 123 disposed at the end portions in the longitudinal direction. For example, a length of the third deposition pattern unit 124 may be greater than a length of the first deposition pattern unit 122 and a length of the second deposition pattern unit 123.

The first single deposition area 131, the second single deposition area 132, and the plurality of deposition areas 133 and 134 respectively disposed in the first deposition pattern unit 122, the second deposition pattern unit 123 and the third deposition pattern unit 124 may include a plurality of pattern portions, respectively.

The first single deposition area 131 may be divided into a plurality of pattern portions 125 in a width direction (Y direction) of the divisional mask 120. The second single deposition area 132 and the plurality of deposition areas 133 and 134 may be divided into a plurality of pattern portions 126 and a plurality of pattern portions 127, respectively, in the same way as the plurality of pattern portions 125 of the first single deposition area 131.

Since the pattern portions 125, 126, and 127 have the substantially same shape, the pattern portions 125 of the first single deposition area 131 will be explained as an example below.

The plurality of pattern portions 125 may be arranged in the width direction of the divisional mask 120. The respective pattern portions 125 may be continuously disposed in the width direction of the divisional mask 120. In the present exemplary embodiment, the number of pattern portions 125 is five. However, the number of pattern portions is not limited to five. The respective pattern portions 125 may have the same size. The plurality of pattern portions 125 may all consist of a slit having the same shape.

As illustrated in FIG. 3, one of the pattern portions 125 will be explained in detail as an example hereinafter.

The pattern portion 125 may include a first slit 128 that extends a longitudinal direction of the pattern portion 125 and a plurality of second slits 129 and a plurality of third slits 130 that are on both sides of the first slit 128 with respect to the first slit 128.

In detail, the first slit 128 may extend from a center portion of the pattern portion 125 in the longitudinal direction of the pattern portion 125. The longitudinal direction of the pattern portion 125 corresponds to the longitudinal direction of the divisional mask 120. The first slit 128 may be at least one slit of a stripe shape. In the present embodiment, the first slit 128 is illustrated as one slit of a stripe shape as an example. However, the first slit 128 may be a plurality of slits spaced apart from each other.

The second slits 129 may be on one side of the first slit 128 (which is a left side area LA of FIG. 3) in a width direction of the pattern portion 125, and the third slits 130 may be on the other side of the first slit 128 (which is a right side area RA of FIG. 3). The width direction of the pattern portion 125 corresponds to the width direction of the divisional mask 120. The second slits 129 and the third slits 130 may be a groove of a dot shape. The second slits 129 and the third slits 130 may be the same pattern. The second slits 129 and the third slits 130 may be symmetrically arranged about the first slit 128.

Similarly, the first single deposition area 131 is divided into the plurality of pattern portions 125, and the pattern portion 125 is subdivided into the dot-shaped second and third slits 129 and 130 that are arranged with respect to the stripe-shaped first slit 128 so that the deformation of the divisional mask 120 according to a size of the first deposition pattern unit 122, for example, a width of the first deposition pattern unit 122, can be reduced.

The number of pattern portions 125 may be five, and the five pattern portions 125 may be continuously arranged in the width direction of the divisional mask 120. The five pattern portions 125 may form the first single deposition area 131. The five pattern portions 125 may have the same shape and may be continuously arranged. The first single deposition area 131 including the five pattern portions 125 may have the substantially same patterns as deposit patterns of sub-pixels on a display substrate 150 of FIG. 1 in an organic light-emitting display apparatus.

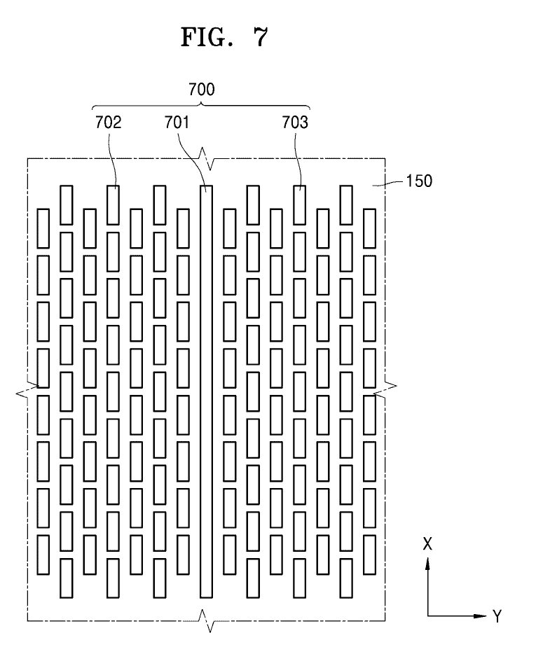

For example, as illustrated in FIG. 7, when a red light-emitting layer 700 is disposed on the display substrate 150, deposit patterns, for example, a first deposition pattern 701 and second deposition patterns 702 and 703, of the red light-emitting layer 700 respectively corresponding to patterns of the first, second, and third slits 128, 129, and 130 of FIG. 3, may be formed in a plurality of sub-pixels over the display substrate 150. The deposition patterns 701, 702, and 703 of the red light-emitting layer 700 may be substantially the same as the patterns of the first, second, and third slits 128, 129, and 130, respectively, of the pattern portion 125 of FIG. 3.

At least one first deposition pattern 701 may be formed on the display substrate 150 to extend in one direction (direction X) of the display substrate 150 to correspond to the first slit 128, and the second deposition patterns 702 and 703 may be formed on the display substrate 150 on both sides of the first deposition pattern 701 with respect to the first deposition pattern 701 to extend in the direction (direction X) of the display substrate 150 and to correspond to the second slits 129 and the third slits 130, respectively. The first deposition pattern 701 and the second deposition patterns 702 and 703 may be repeatedly arranged in the other direction (direction Y) of the display substrate 150.

The first deposition pattern 701 may have a stripe-shaped pattern that extends in the one direction (direction X) of the display substrate 150, like the first slit 128, and the second deposition patterns 702 and 703 may have the same dot-shaped patterns as the second slits 129 and the third slits 130. The second deposition patterns 702 and 703 may be symmetrically disposed about the first deposition pattern 701.

In the present exemplary embodiment, the red light-emitting layer 700 is explained as an example. In addition, deposition patterns may be formed on the display substrate 150 to correspond to a green light-emitting layer and a blue light-emitting layer.

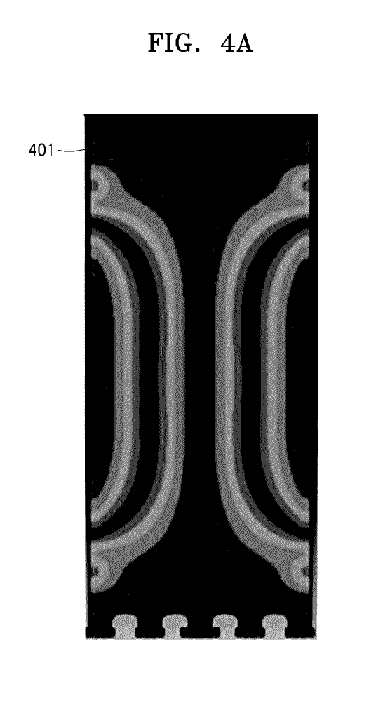

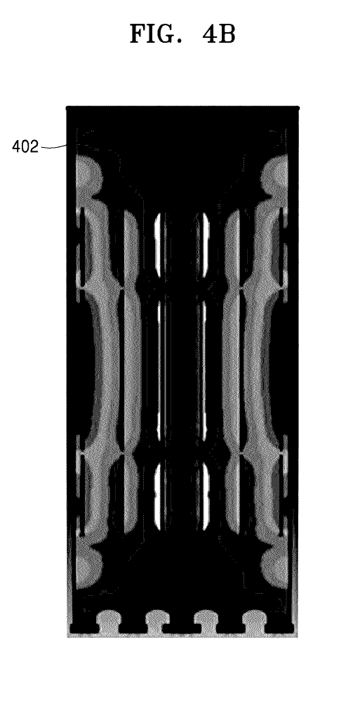

FIG. 4A is a picture showing a deformation amount of a mask 401 according to an experimental-comparison example, and FIG. 4B is a picture showing a deformation amount of a mask 402 according to the present exemplary embodiment.

Referring to FIGS. 4A and 4B, the mask 401 of the comparison example may be a mask including conventional deposition pattern units. The mask 401 is not divided into a plurality of deposition areas. The mask 402 of the present exemplary embodiment may be a mask including deposition pattern units to correspond to the deposition pattern units, as illustrated in FIGS. 2 and 3. A deposition area of the mask 402 may be divided into a plurality of pattern portions, and each pattern portion includes dot-shaped slits disposed on both sides of a stripe-shaped slit.

The deformation amount of the mask 401 of the comparison example is 6.77 micrometers in a width direction of the mask 401. On the other hand, the deformation of the mask 402 of the present exemplary embodiment in a width direction of the mask 402 is 3.12 micrometers.

Thus, in the deformation amounts of the mask 401 of the comparison example and the mask 402 of the present exemplary embodiment in the width direction of the masks 401 and 402 crossing a tensile direction of the masks 401 and 402, the deformation amount of the mask 402 may be reduced to about half of the deformation amount of the mask 401.

FIG. 5 is a diagram illustrating deposition of a thin film on the display substrate 150 using the mask assembly 100 of FIG. 1.

Referring to FIG. 5, a vacuum chamber 501 is provided to deposit a light-emitting layer of an organic light-emitting display apparatus using the mask assembly 100.

A deposition source 502 is disposed at a bottom portion of the vacuum chamber 500, and the mask assembly 100 is disposed at a top portion of the vacuum chamber 500. The mask assembly 100 may include the mask 140 illustrated in FIG. 1. The mask 140 includes at least one divisional mask 120. The mask 140 is mounted on the mask frame 110. The display substrate 150 may be disposed on the mask 140. The magnet 504 may be disposed on the display substrate 150.

Meanwhile, a support member 503 may be disposed at an edge of the mask assembly 100 to fix the mask assembly 100 in the vacuum chamber 500.

A process of depositing a deposition material on the display substrate 150 will be briefly explained below.

First, the display substrate 150 is disposed on the mask 140.

Next, an elevation unit 505 moves the magnet 504 downward toward the display substrate 150 such that the magnet 504 contacts an outside surface of the display substrate 150. The mask 140 and the display substrate 150 are in close contact with each other as a result of a magnet force of the magnet 504. The magnet 504 may include a plurality of magnetic sticks spaced apart from each other and arranged in one direction of the mask 140, for example, a longitudinal direction of the mask 140.

Subsequently, the deposition material is evaporated toward the mask assembly 100 from the deposition source 502. The evaporated deposition material passes through the respective slits of the deposition pattern units 122, 123, and 124 of FIG. 2 formed in the mask 140 and then is deposited in a deposition area of the display substrate 150. The display substrate 150 may be a mother substrate to produce a plurality of organic light-emitting display apparatuses.

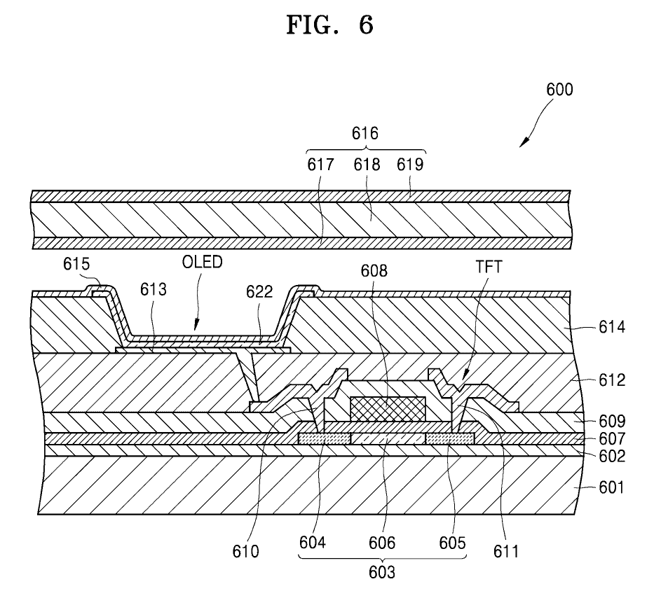

FIG. 6 is a cross-sectional view illustrating a sub-pixel of an organic light-emitting display apparatus 600 in which a light-emitting layer is deposited on a display substrate 601 using the mask assembly 100 of FIG. 1, according to an exemplary embodiment of the present inventive concept.

Referring to FIG. 6, the organic light-emitting display apparatus 600 includes the display substrate 601. The display substrate 601 may include either a flexible insulation material or a rigid insulation material. The display substrate 601 may be transparent, translucent, or opaque.

A barrier film 602 may be disposed on the display substrate 601. The barrier film 602 may cover an entire upper side of the display substrate 601. The barrier film 602 may include an inorganic film or an organic film.

A thin film transistor TFT may be disposed on the barrier film 601. A semiconductor active layer 603 may be disposed on the barrier film 601. The semiconductor active layer 603 may include a source area 604 and a drain area 605 formed by doping p-type impurity ions or P-type impurity ions. A channel area 606 is disposed between the source area 604 and the drain area 605 and is an area without doping impurities.

A gate insulating film 607 may be deposited on the semiconductor active area 603. The gate insulating film 607 may include an inorganic film of silicon oxide, silicon nitride, or a metal oxide. The gate insulating film 607 may be a structure including a single layer or a multilayer.

A gate electrode 608 may be disposed on an area of the gate insulating film 607. The gate electrode 608 may include a single film of gold (Au), silver (Ag), Copper (Cu), nickel (Ni), platinum (Pt), palladium (Pd), aluminum (Al), Molybdenum (Mo), or chrome (Cr), or a multilayer film. The gate electrode 608 may include an alloy of aluminum-neodymium Al:Nd or molybdenum-tungsten Mo:W.

An interlayer insulating film 609 may be disposed on the gate electrode 608. The interlayer insulating film 609 may include an inorganic film of silicon oxide or silicon nitride or an organic film.

A source electrode 610 and a drain electrode 611 may be disposed on the interlayer insulating film 609. In detail, contact holes are formed by selectively removing portions of the gate electrode 608 and the interlayer insulating film 609, and the source electrode 610 is electrically connected to the source area 604, and the drain electrode 611 is electrically connected to the drain area 605, through the contact holes.

A protecting film 612 (passivation film or planarization film) may be disposed on the source electrode 610 and the drain electrode 611. The protecting film 612 may include an inorganic film of silicon oxide or silicon nitride, or an organic film of acryl, polyimide, or Benzocyclobutene BCB.

An organic light-emitting device OLED may be disposed on an upper side of the thin film transistor TFT.

The organic light-emitting device OLED may be formed on the protecting film 612. The organic light-emitting device OLED may include a first electrode 613, an intermediate layer 622 including an organic light-emitting layer (organic emissive layer), and a second electrode 615.

The first electrode 613 may function as an anode and may include various conductive materials. The first electrode 613 may be a transparent electrode or a reflective electrode. For example, when the first electrode 613 is the transparent electrode, the first electrode 613 may include a transparent conductive film. When the first electrode 613 is the reflective electrode, the first electrode 613 may include a reflective film and a transparent film formed on the reflective film.

A pixel-defining film 614 may partially cover the protecting film 612 and the first electrode 613. The pixel-defining film 614 defines a light-emitting area by surrounding a boundary of the first electrode 6131. The first electrode 613 may be patterned to correspond to each sub-pixel. The pixel-defining film 614 may include an organic film or an inorganic film. The pixel-defining film 614 may include a single film or a multi-film.

The intermediate layer 622 may be formed on the first electrode 613 in an area exposed by etching a portion of the pixel-defining film 614. The intermediate layer 622 may be formed by a deposition process. The intermediate layer 622 may be patterned by using the mask assembly 100 of FIG. 1.

The intermediate layer 622 may include the organic emissive layer. The intermediate layer 622 may include the organic emissive layer and at least one of a hole injection layer (HIL), hole transport layer (HTL), electron transport layer (ETL), and electron injection layer (EIL). The present exemplary embodiment is not limited to the above-described intermediate layer 622. The intermediate layer 622 may include the organic emissive layer and at least one of various functional layers.

The second electrode 615 may be disposed on the intermediate layer 622.

The second electrode 615 may function as a cathode. The second electrode 615 may include a transparent electrode or reflective electrode. For example, when the second electrode 615 includes the transparent electrode, the second electrode 615 may include a metal film and a transparent conductive film formed on the metal film. When the second electrode 615 included the reflective electrode, the second electrode 615 may include the metal film.

A plurality of sub-pixels may be formed on the display substrate 601. The respective sub-pixels may be used to realize red light, green light, blue light, or white light. However, the present disclosure is not limited to the above-described sub-pixels.

An encapsulation substrate 616 may be disposed on an upper side of the organic light-emitting device OLED. The encapsulation substrate 616 protects the intermediate layer 622 and other films from external moisture and oxygen. The encapsulation substrate 616 may include rigid glass, a polymer resin, or a flexible film. The encapsulation substrate 616 may include a multilayer having organic films 617 and 619 and an inorganic film 618 which are alternately formed on the organic light-emitting device OLED. The encapsulation substrate 616 may include at least each of the organic films 617 and 619 and the inorganic film 618.

The mask assembly for thin film deposition and the organic light-emitting device OLED fabricated using the same according to an exemplary embodiment of the present inventive concept may reduce deformation of the mask and obtain a thin film with predetermined patterns.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A mask assembly for thin film deposition, the mask assembly comprising:
a mask frame defining and surrounding an opening; and
a mask coupled to the mask frame and comprising a plurality of deposition pattern units formed in a longitudinal direction of the mask and spaced apart from each other,
wherein the respective deposition pattern units comprise a deposition area, and each deposition area is divided into a plurality of pattern portions.

2. The mask assembly of claim 1, wherein the respective pattern portions are continuously arranged in a width direction of the mask.

3. The mask assembly of claim 2, wherein the respective pattern portions have a same size.

4. The mask assembly of claim 2, wherein each pattern portion comprises slits having a same shape.

5. The mask assembly of claim 4, wherein each pattern portion comprises:
a first slit that extends in a longitudinal direction of the pattern portion corresponding to the longitudinal direction of the mask; and
a plurality of second slits and a plurality of third slits respectively disposed on both sides of the first slit.

6. The mask assembly of claim 5, wherein the first slit extends along the longitudinal direction of the pattern portion and comprises at least one stripe-shaped slit.

7. The mask assembly of claim 5, wherein the second slits and the third slits comprise a same pattern.

8. The mask assembly of claim 5, wherein the second slits and the third slits comprise a plurality of dot-shaped slits.

9. The mask assembly of claim 5, wherein the second slits and the third slits are symmetrically arranged to each other.

10. The mask assembly of claim 1, wherein:
the deposition pattern units disposed at both end portions of the mask in the longitudinal direction of the mask each comprise a single deposition area; and
the deposition pattern unit disposed between the both end portions of the mask comprises a plurality of deposition areas.

11. The mask assembly of claim 10, wherein the deposition pattern units disposed at the both end portions comprise a first deposition pattern unit comprising a first single deposition area at one end of the longitudinal direction of the mask and a second deposition pattern unit comprising a second single deposition area at the other end of the longitudinal direction of the mask.

12. The mask assembly of claim 11, wherein each of the first single deposition area and the second single deposition area comprises a single cell area corresponding to a unit display apparatus.

13. The mask assembly of claim 10, wherein the plurality of deposition areas comprise the single deposition areas continuously arranged therein.

14. The mask assembly of claim 13, wherein the plurality of deposition areas comprise a plurality of cell areas corresponding to a plurality of unit display apparatuses, respectively.

15. The mask assembly of claim 10, wherein a size of the deposition pattern portions disposed at the both end portions is greater than a size of the deposition pattern portion disposed between the both end portions.

16. The mask assembly of claim 1, wherein the mask comprises a plurality of divisional masks.

17. An organic light-emitting display apparatus fabricated using a mask assembly for thin film deposition, the organic light-emitting display apparatus comprising:
a display substrate;
a thin film transistor disposed on the display substrate;
an organic light-emitting device comprising:
a first electrode electrically connected to the thin film transistor and disposed on each sub-pixel of the display substrate; and
an intermediate layer comprising a light emissive layer disposed on the first electrode, and a second electrode disposed on the intermediate layer; and
an encapsulation substrate covering the organic light-emitting device,
wherein:
a pattern of the sub-pixel comprises at least one first deposition pattern that extends in one direction of the display substrate and a plurality of second deposition patterns disposed on both sides of the first deposition pattern with respect to the first deposition pattern; and
the first deposition pattern and the second deposition patterns are repeatedly arranged in the other direction of the display substrate.

18. The organic light-emitting display apparatus of claim 17, wherein the first deposition pattern is formed by using a stripe-shaped pattern of the mask assembly extended along the one direction of the display substrate.

19. The organic light-emitting display apparatus of claim 17, wherein the plurality of second deposition patterns are formed by using same dot-shaped patterns of the mask assembly.

20. The organic light-emitting display apparatus of claim 19, wherein the plurality of second deposition patterns are formed by using symmetrically-arranged patterns of the mask assembly.
